(19) United States
(12) Patent Application Publication
(10) Pub. No.: US 2026/0367528 A1
(43) Pub. Date: Nov. 19, 2026

(54) SYSTEM AND METHOD FOR DETERMINING OVERLAY MEASUREMENT OF A SCANNING TARGET

(71) Applicant: KLA Corporation, Milpitas, CA (US)

(72) Inventors: Itay Gdor, Tel-Aviv (IL); Yuval Lubashevsky, Haifa (IL); Iftach Galon, Migdal Ha'emek (IL); Alon Alexander Volfman, Migdal Ha'emek (IL); Nickolai Isakovitch, Tel-Aviv (IL); Daria Negri, Nesher (IL)

(21) Appl. No.: 19/212,229

(22) Filed: May 19, 2025

(51) Int. Cl. G03F 7/00; G01B 11/26

(52) U.S. Cl. CPC G03F 7/70633; G01B 11/26; G03F 7/706837; G03F 7/706849; G03F 7/706851

(57) ABSTRACT

An overlay metrology system includes a controller communicatively coupled to two or more photodetectors. The controller is configured to receive time-varying interference signals from the two or more photodetectors associated with a grating-in-grating structure in one or more cells as an overlay target is scanned in accordance with a metrology recipe. The grating-in-grating structure may include three or more diffraction gratings in the one or more cells, where the three or more diffraction gratings include at least a first feature on a first layer, a second feature on an additional layer, and a third feature on the first layer. The controller is further configured to determine an overlay error between one of the first feature, the second feature, and the third feature of the sample based on the time-varying interference signals.

### TECHNICAL FIELD

The present disclosure relates generally to overlay metrology and, more particularly, to scanning scatterometry overlay metrology.

### BACKGROUND

Overlay metrology generally refers to measurements of the relative alignment of layers on a sample such as, but not limited to, semiconductor devices. An overlay measurement, or a measurement of overlay error, typically refers to a measurement of the misalignment of fabricated features on two or more sample layers. In a general sense, proper alignment of fabricated features on multiple sample layers is necessary for proper functioning of the device.

Demands to decrease feature size and increase feature density are resulting in correspondingly increased demand for accurate and efficient overlay metrology systems. Metrology systems typically generate metrology data associated with a sample by measuring or otherwise inspecting overlay metrology targets distributed across the sample.

Overlay metrology targets are typically designed to provide diagnostic information regarding the alignment of multiple layers of a sample by characterizing an overlay target having target features located on sample layers of interest. Further, the overlay alignment of the multiple layers is typically determined by aggregating overlay measurements of multiple overlay targets at various locations across the sample.

Some overlay metrology targets (e.g., imaging AIM metrology targets) include features in multiple layers which are spatially separated in the plane of the sample and arranged to have a common center of symmetry, where overlay is measurement by the difference in the centers of symmetry between the layer-pairs of interest. Such metrology targets (e.g., imaging AIM metrology targets) require greater space on the sample. Another type of target (e.g., DBO target) may use the same space for both layers thus saving sample space (smaller target size), in some cases it may not be possible to print two or more targets on top of each other, especially in cut mask process layers. Further, measurement of such metrology targets (e.g., imaging AIM metrology targets) is often performed using area imaging, where the measurement mode is less accurate and suffers from tool-induced-inaccuracy.

Additional overlay metrology targets include multiple single overlay targets measured sequentially (e.g., scatterometry overlay (SCOL) metrology targets or Moiré fringe metrology targets). Such metrology targets (e.g., SCOL metrology targets or Moiré fringe metrology targets) include periodic structures configured to produce diffraction patterns that may be analyzed to determine metrology measurements. The throughput of measurements in such metrology targets (e.g., SCOL metrology targets or Moiré fringe metrology targets), containing a plurality of cells occupying a larger surface area of a sample, are reduced as measurement time scales with each additional overlay metrology target to measure.

Therefore, it is desirable to provide systems and methods for curing the above deficiencies.

### SUMMARY

An overlay metrology system is disclosed, in accordance with one or more embodiments of the present disclosure. In embodiment, the system includes an illumination sub-system including an illumination source configured to generate one or more illumination beams and one or more illumination optics configured to direct the one or more illumination beams to an overlay target on a sample as the sample is scanned relative to the one or more illumination beams along a scan direction when implementing a metrology recipe. The overlay target in accordance with the metrology recipe includes a grating-in-grating structure, where the grating-in-grating structure includes three or more diffraction gratings in one or more cells, where the three or more diffraction gratings include at least a first feature on a first layer, a second feature on an additional layer, and a third feature on the first layer, where the grating-in-grating structure is periodic along the scan direction. In embodiments, the system includes a collection sub-system including two or more photodetectors located in a pupil plane to capture diffraction orders from the grating-in-grating structure in the one or more cells when implementing the metrology recipe. In embodiments, the system includes a controller communicatively coupled to the two or more photodetectors, the controller including one or more processors configured to execute program instructions causing the one or more processors to: receive time-varying interference signals from the two or more photodetectors associated with the grating-in-grating structure in the one or more cells as the overlay target is scanned in accordance with the metrology recipe; and determine an overlay error between one of the first feature, the second feature, and the third feature of the sample based on the time-varying interference signals.

An overlay metrology system is disclosed, in accordance with one or more embodiments of the present disclosure. In embodiments, the system includes a controller communicatively coupled to two or more photodetectors, the controller including one or more processors configured to execute program instructions causing the one or more processors to: receive time-varying interference signals from the two or more photodetectors associated with a grating-in-grating structure in one or more cells as an overlay target is scanned in accordance with a metrology recipe, where the grating-in-grating structure includes three or more diffraction gratings in the one or more cells, where the three or more diffraction gratings include at least a first feature on a first layer, a second feature on an additional layer, and a third feature on the first layer, where the grating-in-grating structure is periodic along the scan direction; and determine an overlay error between one of the first feature, the second feature, and the third feature of the sample based on the time-varying interference signals.

A method is disclosed, in accordance with one or more embodiments of the present disclosure. In embodiments, the method includes receiving time-varying interference signals from two or more photodetectors associated with a first feature, a second feature, and a third feature in one or more cells as an overlay target is scanned in accordance with a metrology recipe, where the first feature, the second feature, and the third feature form a grating-in-grating structure, where the grating-in-grating structures includes three or more diffraction gratings, where the first feature is on a first layer, the second feature is on an additional layer, and the third feature is on the first layer, where the grating-in-grating structure is periodic along a scan direction. In embodiments, the method includes determining an overlay error between one of the first feature, the second feature, and the third feature of a sample based on the time-varying interference signals.

An overlay metrology target is disclosed, in accordance with one or more embodiments of the present disclosure. In embodiments, the overlay metrology target includes one or more cells having a grating-in-grating structure, where the grating-in-grating structure includes three or more diffraction gratings arranged on two or more layers of a sample, where the two or more layers of the sample include at least a first layer and a second layer, where the first layer includes a first feature and the second layer includes a second feature, where the first layer further includes a third feature, where the first feature, the second feature, and the third feature form a non-overlapping grating-in-grating structure, where the non-overlapping grating-in-grating structure is periodic along a scan direction.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures in which:

FIG. 1A illustrates a conceptual view of an overlay metrology system for performing scatterometry overlay metrology on overlay targets using pupil manipulations, in accordance with one or more embodiments of the present disclosure.

FIG. 1B illustrates a schematic view of an overlay metrology sub-system, in accordance with one or more embodiments of the present disclosure.

FIG. 2A illustrates a schematic top view of a cell of an overlay target on a sample, in accordance with one or more embodiments of the present disclosure.

FIG. 2B illustrates a schematic side view of a cell of an overlay target on a sample, in accordance with one or more embodiments of the present disclosure.

FIG. 2C illustrates a schematic side view of a cell of an overlay target on a sample, in accordance with one or more embodiments of the present disclosure.

FIG. 3A illustrates a top view of an illumination pupil in an illumination pupil plane of the overlay metrology sub-system, in accordance with one or more embodiments of the present disclosure.

FIG. 3B illustrates a top view of a collection pupil in the collection pupil plane of the overlay metrology sub-system including grating diffraction lobes associated with the overlay target, in accordance with one or more embodiments of the present disclosure.

FIG. 4A illustrates a schematic top view of a cell of an overlay target on a sample, in accordance with one or more embodiments of the present disclosure.

FIG. 4B illustrates a plot of voltage signal associated with gratings of the overlay target, in accordance with one or more embodiments of the present disclosure.

FIG. 5 illustrates a flow diagram illustrating steps performed in a method for scanning overlay metrology of overlay targets, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to scanning scatterometry overlay using overlay targets including grating-in-grating structures, where the grating-in-grating structures includes three or more diffraction gratings arranged in a grating-in-grating configuration. For example, the three or more diffraction gratings may be arranged in two or more layers and be non-overlapping. For instance, the three or more diffraction gratings may not be directly stacked on top of each other, but instead arranged such that each respective diffraction grating of the three or more diffraction gratings may be scanned sequentially on each respective layer of the two or more layers. In this regard, as the target is scanned by an illumination beam, a first diffraction grating on a first layer may be scanned, a second diffraction grating on a second layer may be scanned, and then a third diffraction grating on the first layer may be scanned.

For the purposes of the present disclosure, the term “scatterometry metrology” is used to broadly encompass the terms “scatterometry-based metrology” and “diffraction-based metrology” in which a sample having periodic features on one or more sample layers is illuminated with an illumination beam having a limited angular extent and one or more distinct diffraction orders are collected for the measurement. Further, the term “scanning metrology” is used to describe metrology measurements generated when a sample is in motion relative to illumination used for a measurement. In a general sense, scanning metrology may be implemented by moving the sample, the illumination, or both.

Embodiments of the present disclosure are directed to systems and methods for scanning overlay metrology based on time-varying interference signals from grating-in-grating structures in a collection pupil plane. It is contemplated herein that measurement conditions leading to overlapping diffraction orders of a grating-in-grating structure may lead to interference. Such interference signals may include information associated with asymmetries in the target structure such as, but not limited to, overlay between the gratings, and the like. It is further contemplated herein that scanning the grating-in-grating structures relative to an illumination beam (or vice versa) may provide characterization of the position-dependent overlay of the grating-in-grating structure and may enable the determination of asymmetries such as, but not limited to, overlay. For example, overlay may be determined based on a center of symmetry of a respective layer (or grating) of the overlay target, where the center of symmetry is determined based on phase extraction information from the overlay target.

Some embodiments of the present disclosure are directed to scanning scatterometry overlay metrology based on time-varying interference signals associated with overlapping diffraction lobes from gratings of a grating-in-grating structure. For instance, scanning-based scatterometry measurement techniques may include fast detectors to capture time-varying interference signals generated as the sample is scanned. The detectors may be placed in the pupil plane at locations of overlap between selected diffraction orders to capture time-varying interference signals as the sample is scanned. Various non-limiting scanning scatterometry overlay metrology techniques are described in U.S. Pat. No. 11,300,405 issued on Apr. 12, 2022; U.S. Pat. No. 11,378,394, issued on Jul. 5, 2022; U.S. Patent Publication No. 2023/0314319, published on Oct. 15, 2023; U.S. Patent Publication No. 2023/0314344, published on Oct. 15, 2023; U.S. Pat. No. 11,796,925, issued on Oct. 24, 2023; U.S. Patent Publication No. 2024/0167813, published on May 23, 2024; and U.S. Pat. No. 12,235,588, issued on Feb. 25, 2025, which are all incorporated herein by reference in their entireties. It is contemplated herein that the systems and methods of the above incorporated references may be extended or otherwise adapted to provide overlay measurements of grating-in-grating structures.

Some embodiments of the present disclosure are directed to providing recipes for configuring an overlay metrology tool. An overlay metrology tool is typically configurable according to a recipe including a set of parameters for controlling various aspects of an overlay measurement such as, but not limited to, the illumination of a sample, the collection of light from the sample, or the position of the sample during a measurement. In this way, the overlay metrology tool may be configured to provide a selected type of measurement for one or more overlay target designs of interest. For example, a metrology recipe may include illumination parameters such as, but not limited to, a number of illumination beams, an illumination wavelength, an illumination pupil distribution (e.g., a distribution of illumination angles and associated intensities of illumination at those angles), a polarization of incident illumination, or a spatial distribution of illumination. By way of another example, a metrology recipe may include collection parameters such as, but not limited to, a collection pupil distribution (e.g., a desired distribution of angular light from the sample to be used for a measurement and associated filtered intensities at those angles), collection field stop settings to select portions of the sample of interest, polarization of collected light, wavelength filters, positions of one or more detectors (e.g., photodetectors) or parameters for controlling the one or more detectors. By way of a further example, a metrology recipe may include various parameters associated with the sample position during a measurement such as, but not limited to, a sample height, a sample orientation, whether a sample is static during a measurement, or whether a sample is in motion during a measurement (along with associated parameters describing the speed, scan pattern, or the like).

The grating-in-grating structure may generally be formed as portions of overlay targets and may generally be located anywhere on the sample. Further, overlay targets may include one or more measurement cells, where each cell includes at least one diffraction grating that is not stacked (i.e., not overlapping). An overlay measurement may then be based on any combination of measurements of the various cells of the overlay target. For example, multiple cells of an overlay target may be designed with different intended offsets (e.g., gratings in the various layers of the sample that are intentionally misaligned with known offset values), which may improve the accuracy and/or sensitivity of the measurement.

In embodiments, the properties of the grating-in-grating structure (e.g., pitches of the constituent gratings, or the like) and the measurement conditions (e.g., illumination wavelength, illumination incidence angle, collection angle, or the like) are arranged or otherwise selected (e.g., using a metrology recipe) to provide a selected distribution of diffraction and/or combined diffraction orders and to further provide that photodetectors are placed at suitable locations to capture these orders to generate time-varying interference signals of interest.

It is contemplated herein that scatterometry overlay metrology as disclosed herein may provide numerous benefits. For example, the system and method disclosed herein may utilize multi-layer overlay targets including non-stacked gratings. By way of another example, overlay measurements may be determined in a single metrology measurement, where one or more layers of the metrology target are not stacked. For instance, the gratings of the multi-layer overlay target may sequentially interact with one or more illumination beams when the target is scanned. In this regard, a region of interest may be used during phase extraction to ensure that the gratings start at the same location. By way of another example, the system and method disclosed herein may enable grating-in-grating overlay targets, where printing different pitches stacked on top of each other is not allowed due to design rules. Additionally, where the overlay target includes grating-in-grating structures with identical pitches, the target may reduce tool-induced shift (TIS) errors. Further, the system and method disclosed herein may improve target accuracy by allowing measurement of extremely small target features (e.g., Critical Dimension, pitch, or the like) that are closer to the size of the actual device. The system and method disclosed herein may further not be impacted by symmetric process variation and amplitude asymmetries induced by asymmetric process variations.

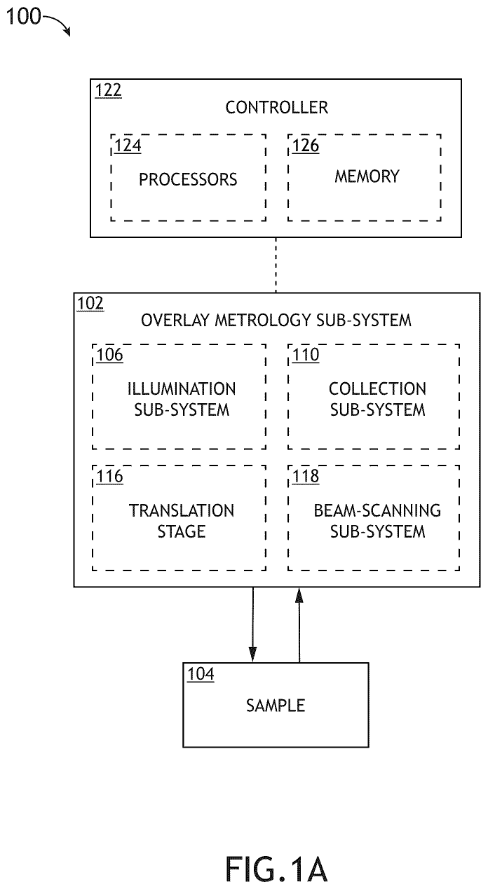

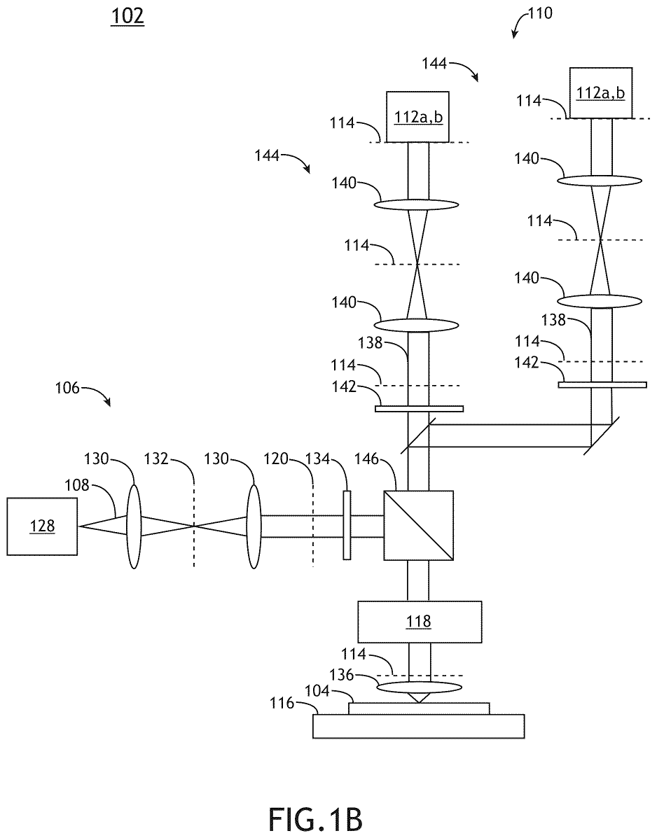

Referring now to FIGS. 1A-5, systems and methods for determining overlay measurements of a scanning target, are described in greater detail in accordance with one or more embodiments of the present disclosure.

FIG. 1A is a conceptual view of an overlay metrology system 100 for performing scatterometry overlay metrology on a grating-in-grating metrology target, in accordance with one or more embodiments of the present disclosure.

In embodiments, the overlay metrology system 100 includes an overlay metrology sub-system 102 to perform scatterometry overlay measurements of a sample 104. For example, the overlay metrology sub-system 102 may perform scatterometry overlay measurements on portions of the sample 104 having grating-in-grating structures. In embodiments, the overlay metrology sub-system 102 includes an illumination sub-system, a collection sub-system 110, a translation stage 116, and a beam-scanning sub-system 118. In embodiments, the system 100 includes a controller 122. The controller 122 includes one or more processors 124 and memory 126.

The one or more processors 124 may be configured to execute a set of program instructions maintained in the memory device 126. For example, the one or more processors 124 may be configured to receive one or more signals from two or more photodetectors as an overlay target is scanned along a stage-scan direction by the translation stage 116 when implementing a metrology recipe. By way of another example, the one or more processors 124 may be configured to determine one or more differential signals between the two or more photodetectors for each measurement cell of the plurality of measurement cells based on the received one or more signals. By way of another example, the one or more processors 124 may be configured to determine an overlay measurement based on the determined one or more differential signals.

FIG. 1B is a schematic view of the overlay metrology sub-system 102, in accordance with one or more embodiments of the present disclosure.

In embodiments, the illumination sub-system 106 is configured to generate illumination in the form of one or more illumination beams 108 to illuminate the sample 104 and the collection sub-system 110 is configured to collect light from the illuminated sample 104. For example, the one or more illumination beams 108 may be angularly limited on the sample 104 such that grating-in-grating structures (e.g., in one or more cells of an overlay target) may generate discrete diffraction orders. Further, the one or more illumination beams 108 may be spatially limited such that they may illuminate selected portions of the sample 104. For instance, each of the one or more illumination beams 108 may be spatially limited to illuminate a particular cell of an overlay target. In embodiments, the one or more illumination beams 108 underfill a particular cell of an overlay target.

The collection sub-system 110 may then collect at least some diffraction orders associated with diffraction of the illumination beam 108 from the grating-in-grating structure. In embodiments, the collection sub-system 110 may include at least two photodetectors 112a,b positioned in a collection pupil plane 114 at locations associated with time-varying interference signals indicative of overlay. For example, as will be described in greater detail below, suitable locations for the photodetectors 112a,b may include, but are not limited to, locations associated with positive and negative diffraction orders or locations associated with overlap between diffraction orders of the constituent gratings of a grating-in-grating structure (e.g., an overlap region between first-order diffraction of each grating and 0-order diffraction). In embodiments, the collection sub-system 110 may include an area sensor positioned in a collection pupil plane 114 at a location associated with time-varying interference signals indicative of overlay.

In embodiments, the translation stage 116 is configured to scan the sample 104 through a measurement field of view of the overlay metrology sub-system 102 during a measurement to implement scanning metrology.

In embodiments, the beam-scanning sub-system 118 is configured to modify or otherwise control a position of at least one illumination beam 108 on the sample 104. For example, the beam-scanning sub-system 118 may scan the illumination beam 108 in a direction orthogonal to a scan direction (e.g., a direction in which the translation stage 116 scans the sample 104) during a measurement.

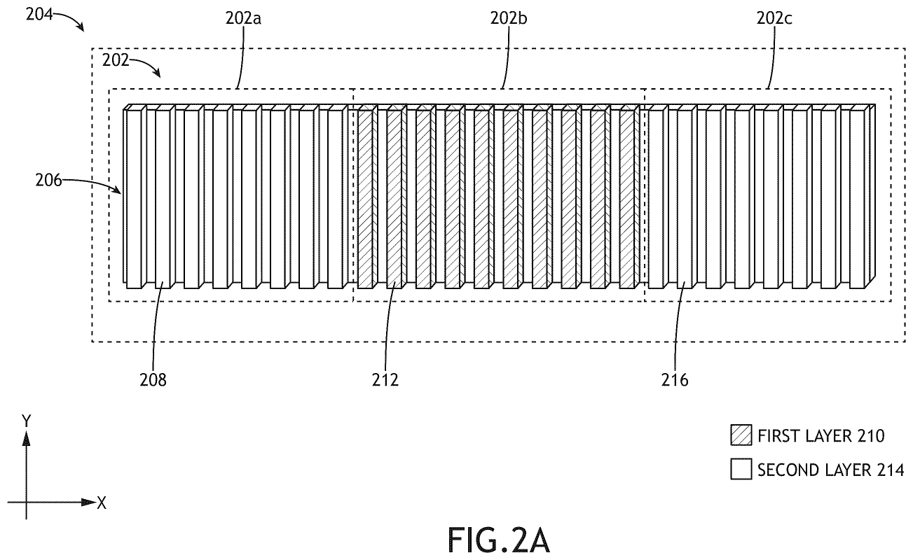

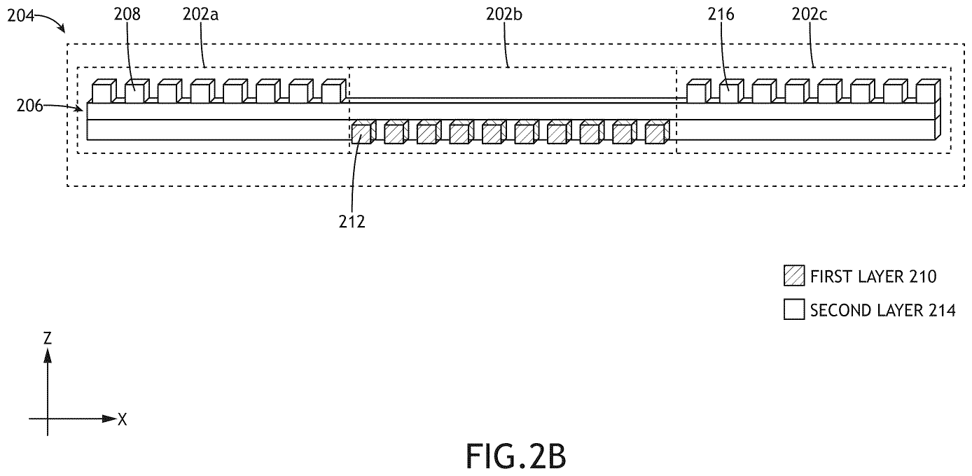

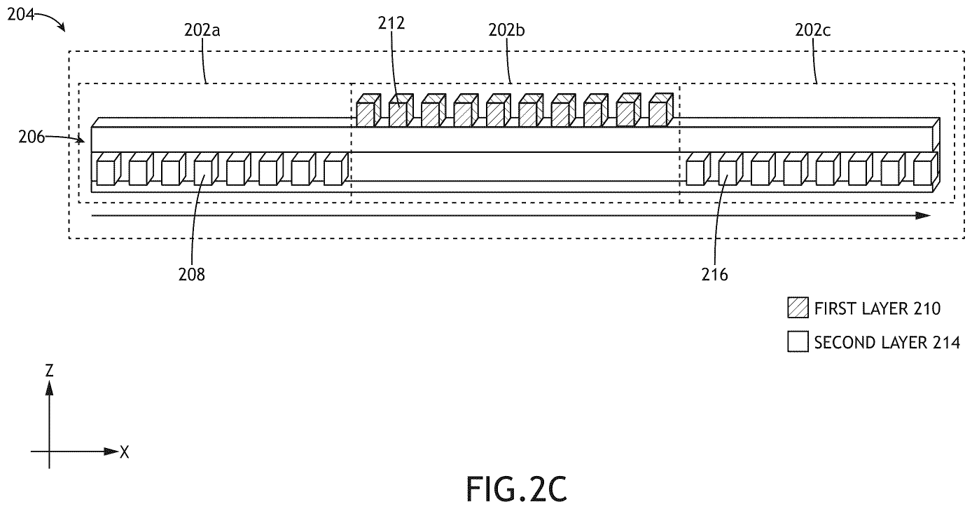

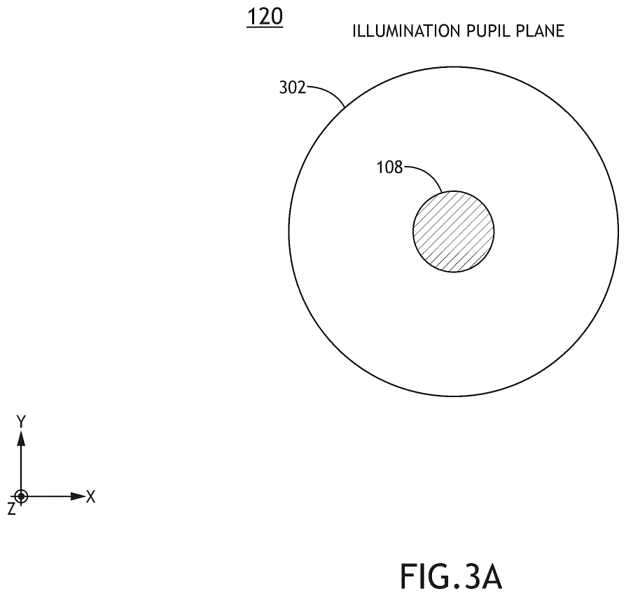

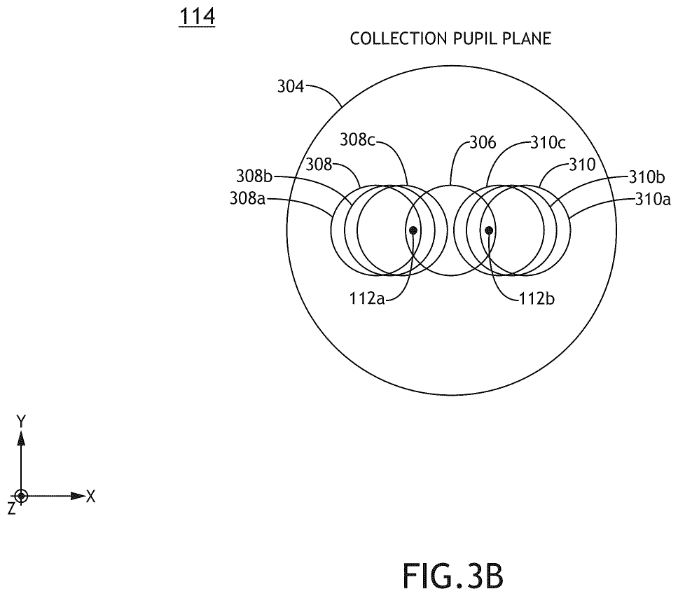

Referring now to FIGS. 2A-3B, the collection of diffraction orders from grating-in-grating structures and the placement of the photodetectors 112a,b for scanning scatterometry overlay metrology is described in greater detail, in accordance with one or more embodiments of the present disclosure.

FIGS. 2A-2C are schematic views of one or more cells 202, in accordance with one or more embodiments of the present disclosure.

In embodiments, the overlay target 204 includes one or more cells 202, where any particular cell 202 of the one or more cells 202 may include a grating-in-grating structure 206 with a periodicity along any direction. The one or more cells 202 may include a plurality of cells 202. For example, the plurality of cells 202 may include a first cell 202a, a second cell 202b, and a third cell 202c.

In embodiments, the grating-in-grating structure 206 includes three or more diffraction gratings, where the respective diffraction gratings in the grating-in-grating structure 206 are not stacked. For example, the grating-in-grating structure 206 may include a first feature 208 located on a first layer 210 of the sample 104, a second feature 212 located on a second layer 214 of the sample 104, and a third feature 216 located on the first layer 210, where the first feature 208, the second feature 212, and the third feature 216 are arranged along the scan direction. For instance, the second feature 212 may be arranged adjacent to the first feature 208, such that the first feature 208 does not overlap with the second feature 212.

It is contemplated herein that although FIGS. 2A_2C depict the overlay target 204 including three or more gratings, the overlay target 204 may include two or more gratings, where the two or more gratings are non-overlapping. However, it is noted herein that it may be advantageous to utilize three or more gratings when the speed (or acceleration) of the translation stage is not uniform, such that any discrepancies in the stage speed may be corrected when averaging the center of symmetry (CoS) of the respective features, as discussed further herein.

The different cells 202 of the overlay target 204 may have different configurations of periodicities of the associated gratings. For example, the overlay target 204 may include the first cell 202a including the first feature 208, the second cell 202b including the second feature 212, and the third cell 202c including the third feature 216 having periodicity along a common direction, where the combination of the first, second, and third features (or gratings) may be referred to as the grating-in-grating structure 206.

Referring to FIG. 2B, the first layer 210 may include a top layer of the overlay target 204 and the second layer 214 may include a bottom layer of the overlay target 204.

For example, the first feature 208 and the third feature 216 may be arranged on the top layer and the second feature 212 may be arranged on the bottom layer. In this regard, the overlay target 204 may be positive, meaning the grating-in-grating structure 206 includes a top-bottom-top configuration where the first feature 208 is on the top layer, the second feature 212 is on the bottom layer, and the third feature 216 is on the top layer.

Referring to FIG. 2C, the first layer 210 may include a bottom layer of the overlay target 204 and the second layer 214 may include a top layer of the overlay target 204. For example, the first feature 208 and the third feature 216 may be arranged on the bottom layer and the second feature 212 may be arranged on the top layer. In this regard, the overlay target 204 may be negative, meaning the grating-in-grating structure 206 includes a bottom-top-bottom configuration where the first feature 208 is on the bottom layer, the second feature 212 is on the top layer, and the third feature 216 is on the bottom layer.

The first feature 208 may be associated with a first lithographic exposure, the second feature 212 may be associated with a second lithographic exposure, and the third feature 216 may be associated with a third lithographic exposure, where the first and third lithographic exposures may be on the same layer (as shown in FIGS. 2A-2C) or different layers.

In embodiments, the gratings of the grating-in-grating structure 206 may have identical pitches. For example, the first feature 208, the second feature 212, and the third feature 216 may have identical pitches. It is contemplated that where the grating-in-grating structure 206 has identical pitches, tool-induced-shift (TIS) errors may be reduced.

In embodiments, the gratings of the grating-in-grating structure 206 may have different pitches. For example, the first feature 208, the second feature 212, and/or the third feature 216 may have different pitches. It is contemplated herein that using different pitches may reduce ambiguity of the signal origin in the interface.

It is noted that the configurations depicted in FIGS. 2A-2C are provided merely for illustrative purposes and shall not be construed as limiting the scope of the present disclosure. As such, the grating-in-grating structure 206 may be formed of any number of layers with any variety of pitches. Further, the overlay target 204 may include any number of cells 202 suitable for measurement. Additionally, the cells 202 may be distributed in any pattern or arrangement. In embodiments, the overlay target 204 includes one or more cell groupings distributed along a scanning direction (e.g., a direction of motion of the sample 104), where cells 202 within each particular cell grouping are oriented to have grating-in-grating structures 206 with periodicity along a common direction. In this way, all cells 202 within a particular cell grouping may be imaged at the same time while the sample 104 is scanned through a measurement field of view of the collection sub-system 110.

Referring now to FIGS. 3A-3B, various non-limiting configurations for the generation and measurement of time-varying interference signals from the grating-in-grating structure 206 in the one or more cells 202 of the overlay target 204 are described in accordance with one or more embodiments of the present disclosure.

FIG. 3A is a top view of an illumination pupil 302 in an illumination pupil plane 120 of the overlay metrology sub-system 102, in accordance with one or more embodiments of the present disclosure. For example, the illumination pupil plane 120 may correspond to a pupil plane in the illumination sub-system 106 as illustrated in FIG. 1B. In embodiments, the illumination sub-system 106 illuminates the overlay target 204 with the one or more illumination beams 108 at normal incidence (or near-normal incidence) as illustrated in FIG. 3A. Further, the one or more illumination beams 108 may illuminate the overlay target 204 with a limited range of incidence angles as illustrated by the limited size in the collection pupil plane 114. In this regard, the overlay target 204 may diffract the one or more illumination beams 108 into discrete diffraction orders.

FIG. 3B illustrates a non-limiting configuration for capturing time-varying interference signals from the overlay target 204 with the grating-in-grating structure 206 in a scanning configuration.

In particular, FIG. 3B illustrates a non-limiting configuration of diffraction orders of the illumination beam 108, associated with the overlay metrology target shown in FIGS. 2A-2C, in the collection pupil plane 114 and associated positions of the photodetectors 112a,b suitable for capturing time-varying interference signals from which an overlay measurement may be extracted. In particular, FIG. 3B′ illustrates 0-order diffraction 306, −1 order grating diffraction 308, and +1 order grating diffraction 310 distributed along the direction of periodicity of the grating-in-grating structure 206 (e.g., the X direction here) in the collection pupil plane 114. For example, the −1 order grating diffraction 308a and the +1 order grating diffraction 310a may be associated with grating diffraction from first feature 208, the −1 order grating diffraction 308b and the +1 order grating diffraction 310b may be associated with grating diffraction from second feature 212, and the −1 order grating diffraction 308c and the +1 order grating diffraction 310c may be associated with grating diffraction from third feature 216, where the diffraction angles are based on the pitches of the gratings and illumination wavelength. In this regard, the respective diffraction lobes of the +1 order grating diffraction 308a-c from the respective layers 210, 214 may overlap and the −1 order grating diffraction 310a-c from the respective layers 210, 214 may overlap, where the first-order grating diffraction from each overlaps with the 0-order grating diffraction.

It is contemplated herein that photodetectors 112a,b placed at locations in the collection pupil plane 114 associated with diffraction lobes (e.g., areas at which first-order diffraction lobes may overlap with 0-order diffraction lobes) may capture time-varying interference signals indicative of overlay. It is further contemplated herein that time-varying interference signals associated with diffraction lobes may be captured by a photodetector 112a,b when each of the relevant diffraction lobes (e.g., areas at which first-order diffraction lobes may overlap with 0-order diffraction lobes) are incident on the photodetector 112a,b (e.g., are within a measurement area of the photodetector 112a,b). In this way, the relevant diffraction lobes need not necessarily overlap in the collection pupil plane 114 but rather may overlap on the photodetector 112a,b.

It is recognized herein that the distribution of diffracted orders of the illumination beam 108 by a periodic structure such as the grating-in-grating structure 206 may be influenced by a variety of parameters such as, but not limited to, a wavelength of the illumination beam 108, an incidence angle of the illumination beam 108 in both altitude and azimuth directions, pitches of the gratings of the grating-in-grating structure 206, or a numerical aperture (NA) of a collection lens. Accordingly, in embodiments of the present disclosure, the illumination sub-system 106, the collection sub-system 110, and the overlay target 204 may be configured (e.g., according to a metrology recipe defining a selected set of associated parameters) to provide a desired distribution of diffraction orders in a collection pupil plane 114 suitable for generating time-varying interference patterns indicative of overlay. For example, the illumination sub-system 106 and/or the collection sub-system 110 may be configured to generate measurements on the grating-in-grating structure 206 having selected range of periodicities to provide a desired distribution in the collection pupil plane 114. Further, various components of the illumination sub-system 106 and/or the collection sub-system 110 (e.g., stops, pupils, or the like) may be adjustable to provide the desired distribution in the collection pupil plane 114.

It is to be understood, however, that the particular configuration illustrated in FIG. 3B and the associated description is not limiting. In particular, it is contemplated herein that the time-varying interference signals may be captured using various metrology overlay techniques, as generally discussed in U.S. Pat. No. 11,300,405, issued on Apr. 12, 2022; U.S. Pat. No. 11,378,394, issued on Jul. 5, 2022; U.S. Patent Publication No. 2023/0314319, published on Oct. 5, 2023; U.S. Patent Publication No. 2023/0314344, published on Oct. 5, 2023; U.S. Pat. No. 11,796,925, issued on Oct. 24, 2023; U.S. Patent Publication No. 2024/0167813, published on May 23, 2024; and U.S. Pat. No. 12,235,588, issued on Feb. 25, 2025.

It is further contemplated, as described previously herein, the 0-order diffraction 306 need not necessarily overlap with the −1 order grating diffraction 308 and the +1 order grating diffraction 310 in the collection pupil 304 as illustrated in FIG. 3B. Rather, in embodiments, these diffraction lobes are sufficiently close together that the 0-order diffraction 306 overlaps with the −1 order grating diffraction 308 on a first photodetector 112a and the 0-order diffraction 306 overlaps with the +1 order grating diffraction 310 on a second photodetector 112b.

It is contemplated herein that the phase of each of the grating diffraction orders (e.g., the first-order diffraction 308,310) may oscillate during a scan to form time-varying interference signals and overlay may be determined based on these oscillations. As a result, an overlay measurement may be performed by capturing and comparing these time-varying interference patterns. For example, the phase differences of the −1 order and +1 order grating diffraction 308, 310 from each individual grating of the one or more features 208, 212, 216 may be used to measure the position of the grating relative to the optical system, as will be discussed further herein.

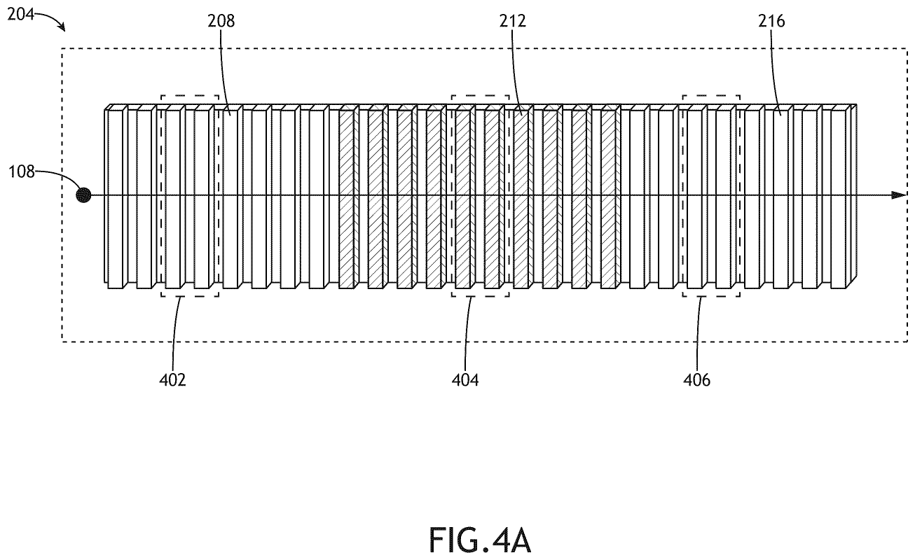

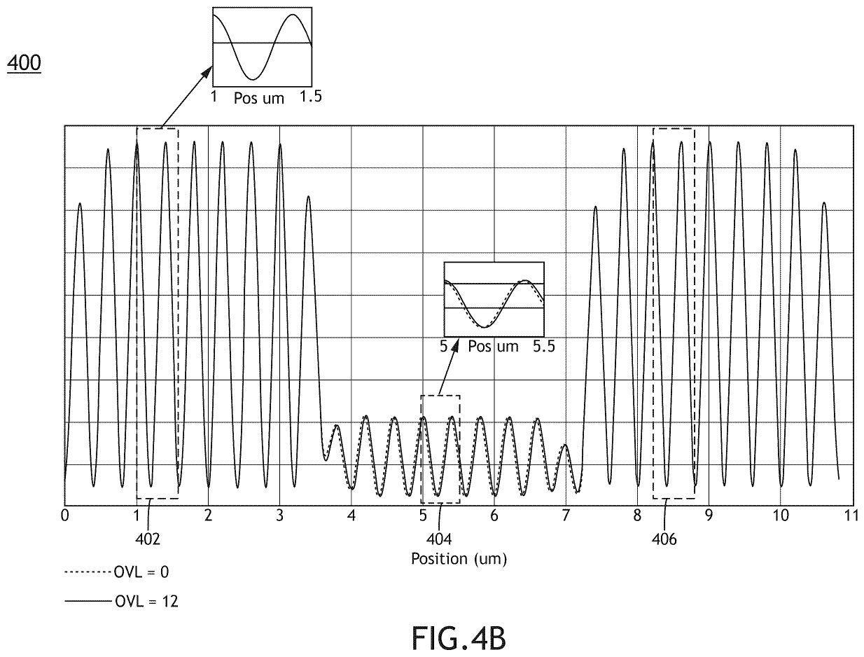

Referring generally to FIGS. 4A-4B, in embodiments, the overlay metrology target 204 is scanned by the one or more illumination beams 108 of the illumination sub-system 106. Referring to FIG. 4A, the overlay metrology target 204 may be scanned by the one or more illumination beams 108 arranged along the scan direction, where the one or more illumination beams 108 sequentially interact with gratings of the grating-in-grating structure 206 as the overlay metrology target 204 is scanned (e.g., the first feature 208 is scanned first, the second feature 212 is scanned second, and the third feature 216 is scanned third).

In embodiments, while the illumination beam 108 scans over the overlay target 204, the first-order signals may be mixed with the 0-order signals and collected separately in time.

For example, the overlapping area between the first-order signals and the 0-order signals may oscillate as a function of illumination spot location, as shown and described by Equation 1 below.

$${I}_{\pm 1} = {\vert {E}_{0} + {E}_{\pm 1} \vert}^{2} = {\vert {E}_{0} \vert}^{2} + {\vert {E}_{\pm 1} \vert}^{2} + 2 \vert {E}_{0} {E}_{\pm 1} \vert = {I}_{0} + 2 \sqrt{{I}_{0} {I}_{\pm 1}} \times cos [ \frac{2 π X}{P} \pm ∅ ] \qquad Equation 1$$

where I_{±1} is the intensity of the interference signals in the overlap region of the 0-order and first-order signals, respectively, I₀ is the intensity of the interference signal of the 0-order signal, E₀ is the electric field amplitude at 0-order diffraction lobe, E_{±1} is the electric field amplitude at the first-order diffraction lobes, X is the position of the grating, φ is the optical path difference (OPD), and P is pitch.

In embodiments, the phase differences of the first-order signals from each individual grating 208, 212, 216 may be used to measure the position of the grating relative to the system. The phase difference may be determined using any technique known in the art including, but not limited to, frequency-domain analysis techniques (e.g., Fast Fourier Transform (FFT), fit to known cosine model, or the like) applied to the two time-varying interference signals.

In embodiments, the overlay error between the one or more sample layers associated with the grating-in-grating structure 206 may be determined based on the phase differences. For example, a center of symmetry (CoS) for each layer 210, 214 may be calculated based on the phase differences, where the CoS value is averaged between the two photodetectors 112a,b to eliminate optical path difference. The CoS may be calculated based on Equation 2, shown and described below:

$$C o S = \frac{φ \times P}{2 π} \qquad Equation 2$$

As such, the overlay error may be calculated based on Equation 3.1, as shown and described by:

OVL=CoS_{L1}−CoS_{L2} Equation 3.1

where CoS_{L1} is the center of symmetry (CoS) for the first layer 210 and CoS_{L2} is the CoS for the second layer 214. It is contemplated herein for Equation 3.1 to apply, the respective gratings need to be designed and printed around the same 0-order position at the center of the overlay target 204.

In cases where the gratings are not printed around the same 0-order position at the center of the overlay target 204, it is contemplated herein that the CoS for each of the gratings needs to be calculated and the respective printing offset subtracted thereof. For example, the overlay error between the one or more sample layers associated with the grating-in-grating structure 206 may be determined based on Equation 3.2, as shown and described by:

$$OVL = \frac{( C o {S}_{G 1} - P {O}_{G 1} + C o {S}_{G 3} - P {O}_{G 3} )}{2} - ( C o {S}_{G 2} - P {O}_{G 2} ) \qquad Equation 3.2$$

where CoS_{G1} is the CoS for the first feature 208 on the first layer 210, PO_{G1} is the printing offset for the first feature 208 on the first layer 210, CoS_{G3} is the CoS for the third feature 216 on the first layer 210, PO_{G3} is the printing offset for the third feature 216 on the first layer 210, COS_{G2} is the CoS for second feature 212 on the second layer 214, and PO_{G2} is the printing offset for the second feature 212 on the second layer 214.

FIG. 4A is a schematic view of an illumination beam spot on the overlay target shown in FIG. 2A, in accordance with one or more embodiments of the present disclosure. FIG. 4B is a plot 400 depicting phase extraction information from the overlay target, in accordance with one or more embodiments of the present disclosure.

Referring to FIG. 4A, in embodiments, the overlay metrology target 204 is scanned by the one or more illumination beams 108 of the illumination sub-system 106, where the first feature 208, the second feature 212, and the third feature 216 of the grating-in-grating structure 206 are scanned sequentially as the overlay metrology target 204 is scanned. For example, as previously discussed herein, the first feature 208, the second feature 212, and the third feature 216 may be arranged along the scan direction. In this regard, the first feature 208 of the first layer 210 may be scanned first, the second feature 212 of the second layer 214 may be scanned second, and the third feature 216 of the first layer 210 may be scanned third.

Referring to FIG. 4B, the plot 400 depicts voltage signal extraction information for the first feature 208, the second feature 212, and the third feature 216. In particular, three signals are shown for the three features 208, 212, 216. In embodiments, one or more regions of interest (ROIs) may be determined for each feature. For example, a first ROI 402 for the first feature 208, a second ROI 404 for the second feature 212, and a third ROI 406 for the third feature 216 may be determined, where the first ROI 402 and the third ROI 406 are determined such that the respective ROIs 402, 406 are symmetrical. In embodiments, the ROIs for the respective features may be determined such that the signal corresponds to a pure cosine signal where its phase can be extracted. As previously discussed herein, once the phase differences have been extracted, the phase extraction information may be used to determine the CoS of the respective feature. For example, the first ROI 402 associated with the first feature 208 may be used to determine the CoS of the first feature 208, the second ROI 404 associated with the second feature 212 may be used to determine the CoS of the second feature 212, and the third ROI 406 associated with the third feature 216 may be used to determine the CoS of the third feature 216. In this regard, three numbers may be calculated by fitting the cosine signal of the respective ROI, where the CoS for the first feature 208 and the third feature 216 may be averaged and then the CoS for the second feature 212 may be subtracted thereto (using Equation 3.1).

However, it is contemplated herein that errors may originate from the stability of the scanning velocity. As such, where the scanning velocity is unstable, the time-varying interference signals may be calibrated (or corrected) to compensate for scanning velocity instability or other sample instabilities. For example, one or more sample reference signals may be used to perform one or more corrections. The one or more sample reference signals may be received from the stage itself (e.g., via a stage encoder) or an external monitoring system. In this regard, the velocity of the stage (or sample) may be monitored and used as an anchor to perform one or more corrections to adjust the phase information of the respective time-varying interference signals.

Referring again to FIG. 1A, additional components of the overlay metrology sub-system 102 are described in greater detail in accordance with one or more embodiments of the present disclosure.

In embodiments, the overlay metrology system 100 includes a controller 122 communicatively coupled to the overlay metrology sub-system 102. The controller 122 may include one or more processors 124 and a memory device 126, or memory. For example, the one or more processors 124 may be configured to execute a set of program instructions maintained in the memory device 126.

In embodiments, the controller 122 captures the interference signals detected by the photodetectors 112a,b. For example, the controller 122 may generally capture data such as, but not limited to, the phases of the time-varying interference signals using any technique known in the art such as, but not limited to, frequency-domain analysis (e.g., FFT), one or more phase-locked loops, and the like. Further, the controller 122 may capture the interference signals, or any data associated with the interference signals, using any combination of hardware (e.g., circuitry) or software techniques.

In embodiments, the controller 122 determines an overlay measurement between layers of the overlay target along the measurement direction based on the comparison of the interference signals. For example, the controller 122 may determine an overlay measurement based on the phases of the interference signals. For instance, U.S. Pat. No. 10,824,079, issued on Nov. 3, 2020, which is incorporated herein by reference in its entirety generally describes the electric field of diffracted orders in a collection pupil and further provides specific relationships between overlay and measured intensity in the pupil plane. It is contemplated herein that the systems and methods disclosed herein may extend the teachings of U.S. Pat. No. 10,824,079 to time-varying interference signals captured by photodetectors placed in overlap regions between 0 and +/−1 diffraction orders. In particular, it is contemplated herein that overlay on a sample may be proportional to the relative phase shift between the two time-varying interference signals.

Further, the controller 122 may calibrate or otherwise modify the overlay measurement based on known, assumed, or measured features of the sample that may also impact the time-varying interference signals such as, but not limited to, sidewall angles or other sample asymmetries.

In embodiments, the illumination sub-system 106 includes an illumination source 128 configured to generate at least one illumination beam 108. The illumination from the illumination source 128 may include one or more selected wavelengths of light including, but not limited to, ultraviolet (UV) radiation, visible radiation, or infrared (IR) radiation.

The illumination source 128 may include any type of illumination source suitable for providing at least one illumination beam 108. In embodiments, the illumination source 128 is a laser source. For example, the illumination source 128 may include, but is not limited to, one or more narrowband laser sources, a broadband laser source, a supercontinuum laser source, a white light laser source, or the like. In this regard, the illumination source 128 may provide an illumination beam 108 having high coherence (e.g., high spatial coherence and/or temporal coherence). In embodiments, the illumination source 128 includes a laser-sustained plasma (LSP) source. For example, the illumination source 128 may include, but is not limited to, an LSP lamp, an LSP bulb, or an LSP chamber suitable for containing one or more elements that, when excited by a laser source into a plasma state, may emit broadband illumination.

In embodiments, the illumination sub-system 106 includes one or more optical components suitable for modifying and/or conditioning the illumination beam 108 as well as directing the illumination beam 108 to the sample 104. For example, the illumination sub-system 106 may include one or more illumination lenses 130 (e.g., to collimate the illumination beam 108, to relay an illumination pupil plane 120 and/or an illumination field plane 132, or the like). In embodiments, the illumination sub-system 106 includes one or more illumination control optics 134 to shape or otherwise control the illumination beam 108. For example, the illumination control optics 134 may include, but are not limited to, one or more apodizers, one or more field stops, one or more pupil stops, one or more polarizers, one or more filters, one or more beam splitters, one or more diffusers, one or more homogenizers, one or more beam shapers, or one or more mirrors (e.g., static mirrors, translatable mirrors, scanning mirrors, or the like).

In embodiments, the overlay metrology sub-system 102 includes an objective lens 136 to focus the illumination beam 108 onto the sample 104 (e.g., an overlay target with overlay target elements located on two or more layers of the sample 104).

In embodiments, the illumination sub-system 106 illuminates the sample 104 with two or more illumination beams 108. Further, the two or more illumination beams 108 may be, but are not required to be, incident on different portions of the sample 104 (e.g., different cells of an overlay target) within a measurement field of view (e.g., a field of view of the objective lens 136). It is contemplated herein that the two or more illumination beams 108 may be generated using a variety of techniques. In embodiments, the illumination sub-system 106 includes two or more apertures at an illumination field plane 132. In embodiments, the illumination sub-system 106 includes one or more beamsplitters to split illumination from the illumination source 128 into the two or more illumination beams 108. In embodiments, at least one illumination source 128 generates two or more illumination beams 108 directly. In a general sense, each illumination beam 108 may be considered to be a part of a different illumination channel regardless of the technique in which the various illumination beams 108 are generated.

In embodiments, the collection sub-system 110 includes the at least two photodetectors 112a,b located at the collection pupil plane 114 configured to capture light from the sample 104 (e.g., collected light 138), where the collected light 138 includes at least the 0-order diffraction 306, the −1 order diffraction 308, and the +1 order diffraction 310 as illustrated in FIG. 3B. The collection sub-system 110 may include one or more optical elements suitable for modifying and/or conditioning the collected light 138 from the sample 104. In embodiments, the collection sub-system 110 includes one or more collection lenses 140 (e.g., to collimate the illumination beam 108, to relay pupil and/or field planes, or the like), which may include, but are not required to include, the objective lens 136. In embodiments, the collection sub-system 110 includes one or more collection control optics 142 to shape or otherwise control the collected light 138. For example, the collection control optics 142 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

In embodiments, the collection sub-system 110 includes two or more collection channels 144, each with a separate pair of photodetectors 112a,b. For example, as illustrated in FIG. 1B, the overlay metrology sub-system 102 may include one or more beamsplitters 146 arranged to split the collected light 138 into the collection channels 144. Further, the beamsplitters 146 may be polarizing beamsplitters, non-polarizing beamsplitters, or a combination thereof. It is to be understood, however, that the illustration of two collection channels 144 in FIG. 1B is provided solely for illustrative purposes and should not be interpreted as limiting. For example, the collection sub-system 110 may include a single collection channel 144 or multiple collection channels 144.

In embodiments, multiple collection channels 144 are configured to collect light from multiple illumination beams 108 on the sample 104. For example, in the case that an overlay target 204 has one or more cells 202 distributed in a direction different than a scan direction, the overlay metrology sub-system 102 may simultaneously illuminate the different cells 202 with different illumination beams 108 and simultaneously capture interference signals associated with each illumination beam 108. Additionally, in embodiments, multiple illumination beams 108 directed to the sample 104 may have different polarizations. In this way, the diffraction orders associated with each of the illumination beams 108 may be separated. For example, polarizing beamsplitters 146 may efficiently separate the diffraction orders associated with the different illumination beams 108. By way of another example, polarizers may be used in one or more collection channels 144 to isolate desired diffraction orders for measurement.

The beam-scanning sub-system 118 may include any type or combination of elements suitable for scanning positions of one or more illumination beams 108. In embodiments, the beam-scanning sub-system 118 includes one or more deflectors suitable for modifying a direction of an illumination beam 108. For example, a deflector may include, but is not limited to, a rotatable mirror (e.g., a mirror with adjustable tip and/or tilt). Further, the rotatable mirror may be actuated using any technique known in the art. For example, the deflector may include, but is not limited to, a galvanometer, a piezo-electric mirror, or a micro-electro-mechanical system (MEMS) device. By way of another example, the beam-scanning sub-system 118 may include an electro-optic modulator, an acousto-optic modulator, or the like.

The deflectors may further be positioned at any suitable location in the overlay metrology sub-system 102. In embodiments, one or more deflectors are placed at one or more pupil planes common to both the illumination sub-system 106 and the collection sub-system 110. In this regard, the beam-scanning sub-system 118 may be a pupil-plane beam scanner and the associated deflectors may modify the positions of one or more illumination beams 108 on the sample 104 without impacting positions of diffraction orders in the collection pupil plane 114. Further, a distribution of one or more illumination beams 108 in an illumination field plane 132 may further be stable as the beam-scanning sub-system 118 modifies positions of the one or more illumination beams 108 on the sample 104. Pupil-plane beam scanning is described generally in U.S. Pat. No. 11,300,524, issued on Apr. 12, 2022, which is incorporated by reference in its entirety.

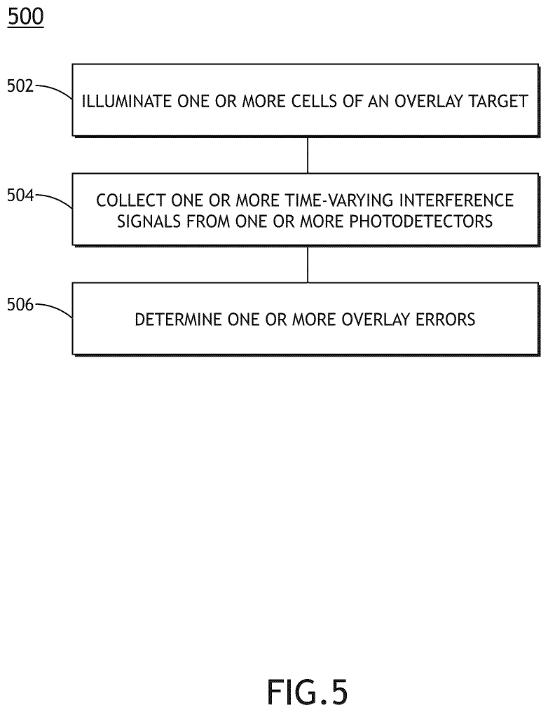

FIG. 5 is a flow diagram illustrating steps performed in a method 500 for scanning overlay metrology of overlay targets, in accordance with one or more embodiments of the present disclosure. Applicant notes that the embodiments and enabling technologies described previously herein in the context of the overlay metrology system 100 should be interpreted to extend to the method 500. It is further noted, however, that the method 500 is not limited to the architecture of the overlay metrology system 100.

In a step 502, one or more cells of an overlay target are illuminated. For example, the one or more cells 202 of the overlay target 204 on the sample 104 are illuminated as the sample 104 is scanned with respect to the illumination.

In one instance, the overlay metrology target 204 may be scanned by the one or more illumination beams 108 arranged along the scan direction, where the one or more illumination beams 108 sequentially interact with gratings of the grating-in-grating structure 206 as the overlay metrology target 204 is scanned (e.g., the first feature 208 is scanned first, the second feature 212 is scanned second, and the third feature 216 is scanned third).

In a step 504, time-varying interference signals from the one or more photodetectors 112a,b may be collected. For example, the time-varying interference signals from the two photodetectors 112a,b placed in regions of the collection pupil associated with overlapping diffraction from the gratings in the grating-in-grating structure 206. For instance, non-limiting configurations may include, but are not limited to, photodetectors may be placed at locations including exclusively grating diffraction orders, both grating diffraction orders and 0-order diffraction, or first-order diffraction from gratings of the grating-in-grating structure 206. In this regard, while the illumination beam 108 scans over the overlay target 204, the first-order signals and the 0-order signals may form time-varying interference signals described herein, where the overlapping area between the 0-order signals and the first-order signals may oscillate as a function of illumination spot location, in accordance with Equation 1 discussed previously herein.

In a step 506, an overlay error between the one or more sample layers associated with the grating-in-grating structure may be determined, in accordance with Equations 2-3.1 (or 3.2) shown and described above. For example, the overlay error between sample layers associated with the grating-in-grating structure in the one or more cells 202 of the overlay target 204 are determined based on the signals from the two photodetectors 112a,b. For instance, the overlay error along a direction of periodicity of the grating-in-grating structure 206 may be proportional to a phase difference between the time-varying interference signals from the two photodetectors. The phase difference may be determined using any technique known in the art including, but not limited to, frequency-domain analysis techniques (e.g., Fast Fourier Transform, fit to known cosine model, or the like) applied to the two time-varying interference signals. Further, in embodiments, overlay measurements of the sample along a particular measurement direction may be generated based on data from multiple cells of the overlay target with grating-in-grating structures having periodicity along the particular measurement direction. The CoS of the respective features 208, 212, 216 may be determined based on the determined phase difference, such that the overlay error may be determined.

It is contemplated herein that the method 500 may be applied to a wide variety of overlay target designs suitable for 1 D or 2D metrology measurements.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An overlay metrology system comprising:
an illumination sub-system comprising:
an illumination source configured to generate one or more illumination beams; and
one or more illumination optics configured to direct the one or more illumination beams to an overlay target on a sample as the sample is scanned relative to the one or more illumination beams along a scan direction when implementing a metrology recipe,
wherein the overlay target in accordance with the metrology recipe includes a grating-in-grating structure, wherein the grating-in-grating structure includes three or more diffraction gratings in one or more cells, wherein the three or more diffraction gratings include at least a first feature on a first layer, a second feature on an additional layer, and a third feature on the first layer, wherein the grating-in-grating structure is periodic along the scan direction;
a collection sub-system comprising:
two or more photodetectors located in a pupil plane to capture diffraction orders from the grating-in-grating structure in the one or more cells when implementing the metrology recipe; and
a controller communicatively coupled to the two or more photodetectors, the controller including one or more processors configured to execute program instructions causing the one or more processors to:
receive time-varying interference signals from the two or more photodetectors associated with the grating-in-grating structure in the one or more cells as the overlay target is scanned in accordance with the metrology recipe; and
determine an overlay error between one of the first feature, the second feature, and the third feature of the sample based on the time-varying interference signals.

2. The overlay metrology system of claim 1, wherein the one or more illumination beams sequentially interact with the first feature, the second feature, and the third feature of the grating-in-grating structure as the sample is scanned relative to the one or more illumination beams.

3. The overlay metrology system of claim 1, wherein the one or more processors are configured to execute program instructions causing the one or more processors to:
extract phase information associated with the time-varying interference signals;
determine one or more regions of interest for each of the three or more diffraction gratings;
determine a center of symmetry for each of the three or more diffraction gratings based on the one or more regions of interest determined and the phase information extracted; and
determine the overlay error between the first feature, the second feature, and the third feature of the sample based on the center of symmetries determined.

4. The overlay metrology system of claim 3, wherein the phase information associated with the time-varying interference signals are extracted using at least one of a Fast Fourier Transform technique or a fit to known cosine model technique.

5. The overlay metrology system of claim 3, wherein a first region of interest associated with the first feature is symmetrical to a second region of interest associated with the third feature.

6. The overlay metrology system of claim 3, wherein the determine the overlay error between the first feature, the second feature, and the third feature of the sample based on the center of symmetries determined comprises:
averaging a first center of symmetry for the first feature and a second center of symmetry for the third feature; and
subtracting a third center of symmetry for the second feature from the averaged first and second center of symmetries.

7. The overlay metrology system of claim 1, wherein the first feature has a first pitch, the second feature has a second pitch, and the third feature has a third pitch, wherein the first pitch is different than the second pitch, wherein the second pitch is different than the third pitch.

8. The overlay metrology system of claim 7, wherein the one or more processors are configured to execute program instructions causing the one or more processors to:
determine a tool-induced shift error based on the time-varying interference signals.

9. The overlay metrology system of claim 1, wherein the first feature, the second feature, and the third feature have identical pitches.

10. The overlay metrology system of claim 1, further comprising:
a translation stage to translate the sample along the scan direction, wherein the one or more illumination optics direct the one or more illumination beams to the overlay target on the sample as the sample is scanned by the translation stage.

11. The overlay metrology system of claim 1, further comprising:
one or more beam-scanning optics to scan the one or more illumination beams along the scan direction.

12. An overlay metrology system comprising:
a controller communicatively coupled to two or more photodetectors, the controller including one or more processors configured to execute program instructions causing the one or more processors to:
receive time-varying interference signals from the two or more photodetectors associated with a grating-in-grating structure in one or more cells as an overlay target on a sample is scanned in accordance with a metrology recipe, wherein the grating-in-grating structure includes three or more diffraction gratings in the one or more cells, wherein the three or more diffraction gratings include at least a first feature on a first layer, a second feature on an additional layer, and a third feature on the first layer, wherein the grating-in-grating structure is periodic along a scan direction; and
determine an overlay error between one of the first feature, the second feature, and the third feature of the sample based on the time-varying interference signals.

13. The overlay metrology system of claim 12, wherein the one or more processors are configured to execute program instructions causing the one or more processors to:
extract phase information associated with the time-varying interference signals;
determine one or more regions of interest for each of the three or more diffraction gratings;
determine a center of symmetry for each of the three or more diffraction gratings based on the one or more regions of interest determined and the phase information extracted; and
determine the overlay error between the first feature, the second feature, and the third feature of the sample based on the center of symmetries determined.

14. The overlay metrology system of claim 13, wherein the phase information associated with the time-varying interference signals are extracted using at least one of a Fast Fourier Transform technique or a fit to known cosine model technique.

15. The overlay metrology system of claim 13, wherein a first region of interest associated with the first feature is symmetrical to a second region of interest associated with the third feature.

16. The overlay metrology system of claim 13, wherein the determine the overlay error between the first feature, the second feature, and the third feature of the sample based on the center of symmetries determined comprises:
averaging a first center of symmetry for the first feature and a second center of symmetry for the third feature; and
subtracting a third center of symmetry for the second feature from the averaged first and second center of symmetries.

17. The overlay metrology system of claim 12, wherein the first feature has a first pitch, the second feature has a second pitch, and the third feature has a third pitch, wherein the first pitch is different than the second pitch, wherein the second pitch is different than the third pitch.

18. The overlay metrology system of claim 17, wherein the one or more processors are configured to execute program instructions causing the one or more processors to:
determine a tool-induced shift error based on the time-varying interference signals.

19. The overlay metrology system of claim 12, wherein the first feature, the second feature, and the third feature have identical pitches.

20. A method comprising:
receiving time-varying interference signals from two or more photodetectors associated with a first feature, a second feature, and a third feature in one or more cells as an overlay target is scanned in accordance with a metrology recipe, wherein the first feature, the second feature, and the third feature form a grating-in-grating structure, wherein the grating-in-grating structure includes three or more diffraction gratings, wherein the first feature is on a first layer, the second feature is on an additional layer, and the third feature is on the first layer, wherein the grating-in-grating structure is periodic along a scan direction; and
determining an overlay error between one of the first feature, the second feature, and the third feature of a sample based on the time-varying interference signals.

21. The method of claim 20, further comprising:
extracting phase information associated with the time-varying interference signals;
determining one or more regions of interest for each of the three or more diffraction gratings;
determining a center of symmetry for each of the three or more diffraction gratings based on the one or more regions of interest determined and the phase information extracted; and
determining the overlay error between the first feature, the second feature, and the third feature of the sample based on the center of symmetries determined.

22. The method of claim 21, wherein the phase information associated with the time-varying interference signals are extracted using at least one of a Fast Fourier Transform technique or a fit to known cosine model technique.

23. The method of claim 21, wherein a first region of interest associated with the first feature is symmetrical to a second region of interest associated with the third feature.

24. The method of claim 21, wherein the determine the overlay error between the first feature, the second feature, and the third feature of the sample based on the center of symmetries determined comprises:
averaging a first center of symmetry for the first feature and a second center of symmetry for the third feature; and
subtracting a third center of symmetry for the second feature from the averaged first and second center of symmetries.

25. An overlay metrology target comprising:
one or more cells having a grating-in-grating structure, wherein the grating-in-grating structure includes three or more diffraction gratings arranged on two or more layers of a sample, wherein the two or more layers of the sample include at least a first layer and a second layer,
wherein the first layer includes a first feature and the second layer includes a second feature, wherein the first layer further includes a third feature,
wherein the first feature, the second feature, and the third feature form a non-overlapping grating-in-grating structure,
wherein the non-overlapping grating-in-grating structure is periodic along a scan direction.

26. The overlay metrology target of claim 25, wherein the first feature, the second feature, and the third feature have identical pitches.

27. The overlay metrology target of claim 25, wherein the first feature has a first pitch, the second feature has a second pitch, and the third feature has a third pitch, wherein the first pitch is different than the second pitch and the third pitch, wherein the second pitch is different than the first pitch and the third pitch.

28. The overlay metrology target of claim 25, wherein the first feature has a first pitch and the second feature has a second pitch, wherein the first pitch is different than the second pitch.
